(19) United States
(12) Patent Application Publication
(10) Pub. No.: US 2012/0227794 A1
(43) Pub. Date: Sep. 13, 2012

(54) THRESHOLD ADJUSTMENT IMPLANTS FOR REDUCING SURFACE RECOMBINATION IN SOLAR CELLS

(75) Inventors: James M. Gee, Albuquerque, NM (US); Prabhat Kumar, Fremont, CA (US)

(73) Assignee: Applied Materials, Inc., Santa Clara, CA (US)

(21) Appl. No.: 13/496,740

(22) PCT Filed: Sep. 20, 2010
(86) PCT No.: PCT/US2010/049537

§ 371 Date: May 29, 2012

Related U.S. Application Data
(60) Provisional application No. 61/243,615, filed on Sep. 18, 2009.

(51) Int. Cl. H01L 31/02; H01L 31/18

(52) U.S. Cl. 136/252; 438/57; 257/E31.002

(57) ABSTRACT

Embodiments of the invention relate to methods of forming solar cell devices to reduce recombination losses and solar cell devices made by such methods, for example back contact solar cells, such as emitter-wrap-through (EWT) solar cells. The methods may include disposing an amount of impurities into a charge compensating region formed on a rear surface of a substrate and forming a rear surface passivation layer over at least a portion of the charge compensating region, wherein the amount of the impurities disposed in the charge compensating region is selected to compensate for an amount of charge formed in the rear surface passivation layer.

### BACKGROUND OF THE INVENTION

1. Field of the Invention

The present invention relates to methods and processes for forming solar cell devices and solar cell devices made by such methods and processes. In particular, the present invention relates to methods and processes for the reduction of recombination losses in solar cell devices and solar cell devices with reduced recombination losses.

2. Description of the Related Art

The efficiency of solar cells is improved by reducing recombination losses. Recombination loss refers to the reaction between electrons and holes in the semiconductor. Recombination can occur due to several physical recombination mechanisms, such as radiative, Auger, and deep-level (commonly known as Shockley-Read-Hall) recombination. Recombination loss in the bulk of the solar cell may occur separately from recombination loss at the surfaces of the solar cell. In general, recombination at the surfaces of a solar cell become relatively more important as the material quality is improved and the device is made thinner. This is particularly true for silicon solar cells where thin substrates are used in order to reduce the cost.

A dielectric layer on the surface of silicon may be used to reduce recombination losses. Such dielectric layers are said to “passivate” the surface because the defect states responsible for the recombination are made electrically inactive, or “passivated”. Passivation layers can include thermally grown SiO₂, deposited layers of various inorganic compounds, or deposited layers of semiconductor materials (e.g., various alloys of a-Si:H).

FIG. 1 schematically depicts a cross-sectional view of a silicon solar cell known in the art. Silicon solar cell 100 is fabricated from a crystalline silicon substrate 110. The substrate 110 includes a base region 101, an emitter region 102, a p-n junction region 103, a dielectric front surface passivation layer 104, a dielectric rear surface passivation layer 115, a front electrical contact 107, and rear electrical contact 108. The p-n junction region 103 is disposed between base region 101 and emitter region 102 of the solar cell, and is the region in which electron-hole pairs are generated when solar cell 100 is illuminated by incident photons. Passivation layer 104 may act as an anti-reflective coating (ARC) layer for solar cell 100 as well as a passivation layer for the surface 105 of emitter region 102. Passivation layer 115 may act as a reflective coating layer for solar cell 100 as well as a passivation layer for the rear surface 106 of substrate 110.

When light falls on the solar cell, energy from the incident photons generates electron-hole pairs on both sides of p-n junction region 103. In a typical, n-type emitter region 102 and p-type base region 101, electrons diffuse across the p-n junction to a lower energy level and holes diffuse in the opposite direction, creating a negative charge on the emitter and a corresponding positive charge build-up in the base. When an electrical circuit is made between the emitter and the base, a current will flow and electricity is produced by solar cell 100. The efficiency at which solar cell 100 converts incident energy into electrical energy is affected by a number of factors, including the recombination rate of electrons and holes in solar cell 100 and the fraction of light that is reflected off backside layers of solar cell 100 and back into the substrate 110.

Recombination occurs when electrons and holes, which are moving in opposite directions in solar cell 100, combine with each other. Each time an electron-hole pair recombines in solar cell 100, charge carriers are eliminated, thereby reducing the efficiency of solar cell 100. Recombination may occur in the bulk silicon of substrate 110 or on either surface 105, 106 of substrate 110. One function of the passivation layer 104 is to minimize the carrier recombination at the surface of the emitter region(s) 102 or the base region 101 over which the passivation layer 104 is formed. Thorough passivation of the surface of a solar cell greatly improves the efficiency of the solar cell by reducing surface recombination.

Surface recombination in silicon is very well understood. See, for example, Armin Aberle, “Surface passivation of crystalline silicon solar cells: a review,” Prog. In Photovoltaics, vol. 8, pp. 473-487 (2000). There are two primary physical mechanisms that are typically employed for reducing surface recombination. In the first mechanism, the density of states responsible for the recombination is reduced. In the second mechanism, a fixed charge at the surface reduces the density of one of the charge carriers to lower the net recombination rate. “Fixed charge” refers to defects in the dielectric near the interface that are charged under normal operating conditions. The charge tends to be a chemical property of the dielectric on the silicon, and may be difficult to modulate to any great extent. Thermally grown oxides tend to have a small positive charge <10¹¹ cm⁻²). Silicon nitride deposited by plasma-enhanced chemical vapor deposition (PECVD) generally has a large positive fixed charge (>10¹² cm⁻²), while aluminum oxide deposited by atomic-layer deposition has a negative fixed charge. Positive fixed charge is useful for passivating n-type surfaces since the positive charge repels the minority-charge carrier (positively charged holes). The opposite is true for dielectrics with negative fixed charge; i.e., these materials are useful for passivating p-type surfaces since the negative charge repels electrons.

Control of the fixed charge is particularly important for back-contact silicon solar cells. Back-contact solar cells have both the positive and negative polarity contacts on the rear of the solar cell. There must be good electrical isolation between the two regions that must also be passivated for low recombination losses. As an example, FIG. 2 shows a schematic illustration of a back-contact cell 200 using the emitter-wrap-through structure (EWT). The emitter 218 is wrapped from the front surface 202 to the rear surface 203 through laser-drilled vias 212 in the EWT cell 200.

The positive-polarity contact and grid (“P-metal”) 220 is separated from the n+ diffusion 218 on the rear surface by a dielectric diffusion barrier 214. The quality of the interface between the dielectric diffusion barrier 214 and the p-type silicon 210 affects the electrical isolation between the n+ diffusion 218 and p-metal contact 220; i.e., the solar cell will be shunted if there is sufficient positive fixed charge at the interface to “invert” the surface. “Inversion” occurs when the surface charge is sufficient to cause the interface to change polarity in charge conductivity. Therefore, there is a need for an improved method of reducing recombination losses in solar cell devices and prevent inversion of regions in solar cells.

### SUMMARY OF THE INVENTION

The present invention generally provides methods and processes for forming solar cell devices. In one embodiment, the method includes disposing an amount of impurities into a charge compensating region formed on a rear surface of a substrate and forming a rear surface passivation layer over at least a portion of the charge compensating region, wherein the amount of the impurities disposed in the charge compensating region is selected to compensate for an amount of charge formed in the rear surface passivation layer.

In another embodiment, a method of forming a solar cell device, includes forming an array of vias in a substrate that is doped with a first doping element, wherein the array of vias is formed between a front surface and a rear surface of the substrate, forming a charge compensating region on a portion of the rear surface, wherein the charge compensating region is doped with a third doping element of the same doping type as the first doping element, forming a dielectric passivation layer on the charge compensating region, forming a doped region on at least a portion of the front surface, on a surface of the vias in the array of vias, and at least a portion of the rear surface, wherein the doped region is doped with a second doping element that is of an opposite doping type to the first doping element, and depositing a first gridline on the rear surface and a distance along the rear surface from the array of vias, wherein the first gridline traverses the dielectric passivation layer and is electrically connected to the substrate doped with the first doping element.

In another embodiment, a solar cell device includes a substrate comprising a semiconductor material doped with a first doping element, the substrate comprising a front surface and a rear surface opposite the front surface, a doped region formed on the front surface and in the substrate, wherein the doped region is doped with a second doping element that is of an opposite doping type to the first doping element, a charge compensating region formed on the rear surface, wherein the charge compensating region is doped with a third doping element of the same doping type as the first doping element, a rear surface passivation layer formed on the charge compensating region, a back contact layer comprising a conductive material formed on the rear surface passivation layer, and a backside contact that traverses the rear surface passivation layer to electrically couple the back contact layer with the semiconductor material.

In another embodiment, a solar cell device includes a substrate having an array of vias formed between a front surface and a rear surface of the substrate, wherein the substrate is doped with a first doping element, a charge compensating region formed on a portion of the rear surface, wherein the charge compensating region is doped with a third doping element of the same doping type as the first doping element, a dielectric passivation layer formed on at least a portion of the charge compensating region, and a doped region formed on at least a portion of the front surface, a surface of the vias in the array of vias, and at least a portion of the rear surface adjacent the charge compensating region, wherein the doped region is doped with a second doping element that is of an opposite doping type to the first doping element.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (Prior Art) schematically depicts a cross-sectional view of a silicon solar cell fabricated from a single or multi-crystalline silicon substrate.

FIG. 2 (Prior Art) schematically depicts a cross-sectional view of an emitter wrap through (EVVT) back-contact crystalline-silicon (c-Si) solar cell.

FIGS. 3A-3D depict cross-sectional views of a portion of a substrate corresponding to various stages of the process illustrated in FIG. 4.

FIG. 4 is depicts processes used to form the solar cell illustrated in FIGS. 3A-3D according to an embodiment of the invention.

FIGS. 5A-5E depict cross-sectional views of a portion of a of emitter wrap through (EWT) c-Si solar cell substrate corresponding to various stages of the process illustrated in FIG. 7.

FIG. 6 depicts a rear surface of an EWT solar cell comprising a gridline disposed over vias architecture.

FIG. 7 depicts processes used to form the solar cell illustrated in FIGS. 5A-5E and FIG. 6 according to an embodiment of the invention.

To facilitate understanding, identical or similar reference numerals have been used, where possible, to designate identical or similar elements that are common to the figures. It is contemplated that elements disclosed in one embodiment may be beneficially utilized on other embodiments without specific recitation.

### DETAILED DESCRIPTION

Embodiments of the present invention contemplate the formation of a solar cell device that has improved efficiency and device electrical properties. In particular, embodiments of the present invention may reduce the recombination losses often associated with solar cell devices. In one embodiment, the solar cell device is processed to alter the affect of charge that is typically formed in dielectric layers to reduce recombination losses in a solar cell. Although silicon solar cells are most commonly used, the present invention is applicable to solar cells comprising any material.

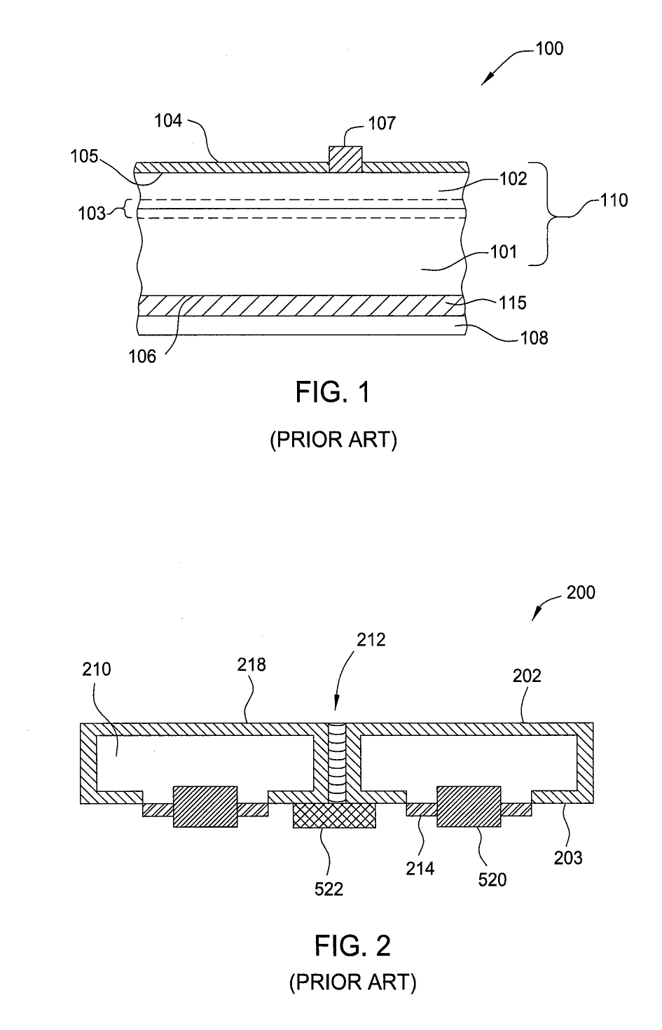

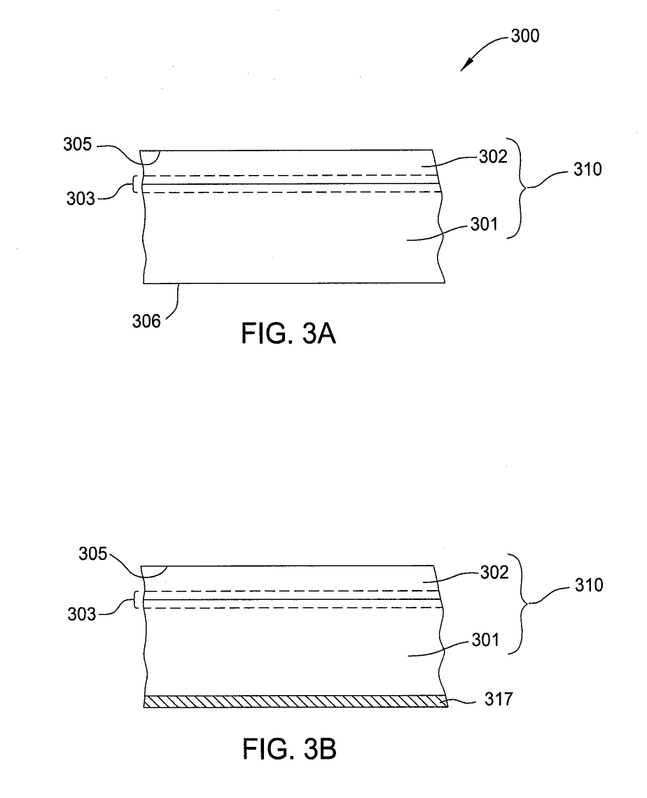

As previously stated in relation to FIGS. 1-2, the quality of the interface between the dielectric diffusion barrier 214 and the p-type silicon 210 affects the electrical isolation between the n+ diffusion 218 and p-metal contact 222; i.e., the solar cell will be shunted if there is sufficient positive fixed charge at the interface to “invert” the surface. “Inversion” occurs when the surface charge is sufficient to cause the interface to change polarity, such as cause a p-type substrate to have a region that has a high concentration of electrons. In some case, the charge of the dielectric passivation layer 214 may be altered to prevent inversion. Similar interfaces in the solar cell device 100 shown in FIG. 1 may also be susceptible to inversion. However, manipulating the charge of the dielectric layers is typically difficult or even impossible depending on the type of solar cells manufactured and the materials used.

Embodiments of the invention may use a low-energy ion implant of a dopant atom to modulate the effective surface charge and reduce recombination losses. Only a low dose is required, so that the cost of the step may be minimized. The ionized dopants near the surface behave electrically like a fixed charge at the interface. One advantage of an implant for silicon solar cells is that commonly used, low cost dielectric coatings may be used for passivating either n-type or p-type silicon solar cells by changing the effective fixed charge. For example, PECVD a-SiNx:H may not passivate p-type Si well in silicon solar cells due to its large positive fixed charge. (The chemical symbol a-SiNx:H indicates that the material is amorphous, has variable stoichiometry, and has considerable hydrogen content. It is frequently abbreviated SiNₓ.) Embodiments of the invention generally provide a method of forming solar cells having a doped portion near dielectric layers to prevent inversion due to the positive charge in the dielectric material. Embodiments of the invention may include forming a shallow implant of ionized charge near dielectric interfaces within a solar cell device that will behave electrically as if it was a fixed charge to prevent inversion.

As will be shown and described below with reference to the Figures, embodiments of the invention include a method of forming a solar cell, including disposing an amount of impurities into a charge compensating region formed on a rear surface of a substrate, and forming a rear surface passivation layer over at least a portion of the charge compensating region, wherein the amount of the impurities disposed in the charge compensating region is selected to compensate for an amount of charge formed in the rear surface passivation layer. The impurities may comprise charge centers in the dielectric. In some embodiments, ion implantation is used to incorporate impurities into the charge compensating region. The impurities may comprise dopants in the silicon. Further details regarding embodiments of the invention are described below

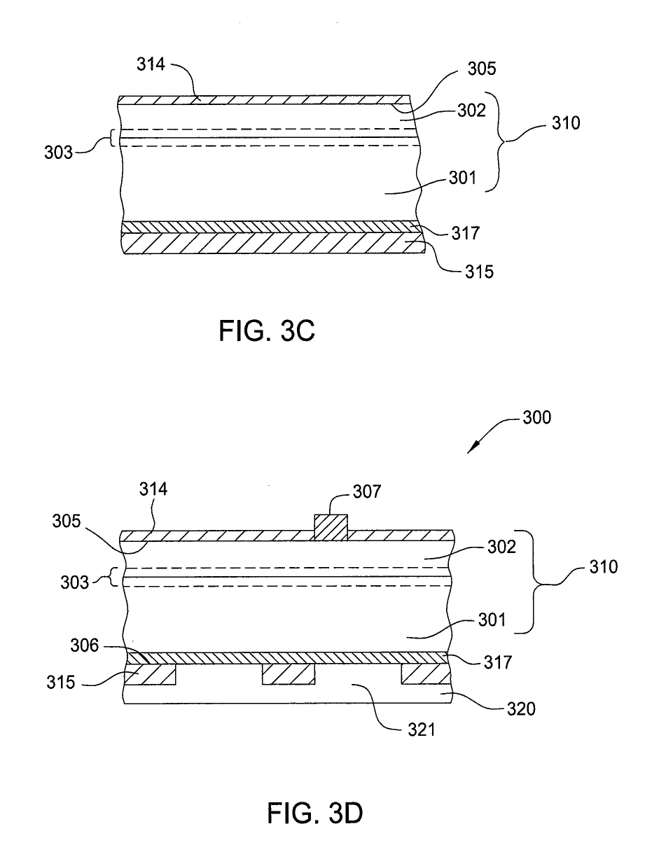

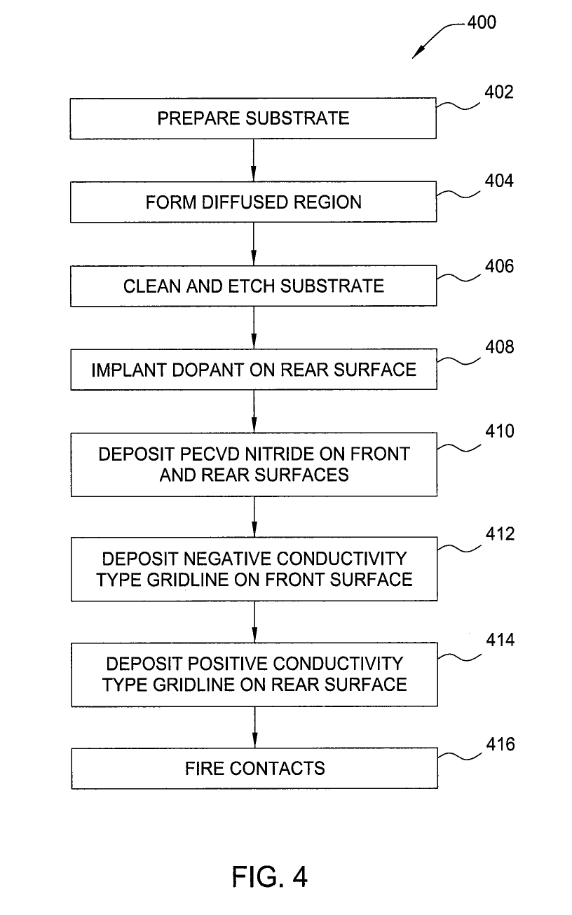

In one embodiment, a solar cell device is formed using a process 400 for passivation of the rear surface of a silicon solar cell with a p-type substrate using a dielectric coating is as illustrated in FIGS. 3A-3D and FIG. 4.

At step 402, the surfaces of the substrate 310, such as the front surface 305, rear surface 306 are etched to remove any undesirable material or crystallographic defects from the wafer production process and the laser machining process. In one embodiment, the etch process may be performed using a batch etch process in which the substrates are exposed to an alkaline etching solution. The substrates can be etched using a wet cleaning process in which they are sprayed, flooded, or immersed in an etchant solution. The etchant solution may be a conventional alkaline cleaning chemistry, such as a potassium hydroxide, or other suitable and cost effective etching solution. This step might additionally texture the surface for improved light collection.

Next, at step 404, as shown in FIG. 3A, a doped region or diffused region 302 is formed on at least a portion the front surface 305 of a substrate comprising a semiconductor material doped with a first doping element. The entire substrate may be diffused with the dopant in another embodiment instead of just the front surface 305. The substrate also has a rear surface 306 opposite the front surface 305. The doped region 302 is doped with a second doping element that is of an opposite doping type to the first doping element. In one embodiment, the diffused region 302 comprises an n⁺ diffusion region (e.g., phosphorous doped) formed in a p-type solar substrate (e.g., boron doped silicon substrate). The diffused region 302 formation process may be performed by use of a conventional furnace doping process that can drive-in one or more dopant atoms. In one example, a POCl₃ diffusion step is performed to produce a diffused region 302 that is an n⁺ doped region. The diffusion process may be done at 850° C. for 20-30 minutes. Alternatively, an inline diffusion process could also be performed, where a dopant source, such as phosphorous source, is applied on both surfaces of the substrate. The substrate may then pass through a belt furnace to diffuse the phosphorous.

In general, it is desirable to create a doping profile in the front surface 502 that is different than the doping profile in the via surface 511 and back surface 503, so that the amount of light collected at the front surface 502 is maximized and the series resistance formed between the front surface 502 and the gridline 520 formed on the rear surface 503 is reduced. In one embodiment, it is desirable to create a doping profile in the portion of the diffused region 518 formed on the front surface 502 that has a sheet resistance of between about 60 Ω/sq and about 200 Ω/sq, and a doping profile in the portion of the diffused region 225 formed on the via surface 511 and the rear surface 503 that has a sheet resistance of between about 20 Ω/sq and about 80 Ω/sq, such as about 40 Ω/sq. In another embodiment, to simplify the solar cell device formation process a single dopant concentration profile is created in the diffused region 518, which is formed across the front surface 502, via surface 511 and portions of the back surface 503. In this configuration, for example, the dopant concentration in the diffused region 518 is doped to achieve a sheet resistance between about 60 Ω/sq and about 80 Ω/sq. In one embodiment, the dopant concentration in the diffused region 518 is doped to achieve a sheet resistance of greater than about 60 Ω/sq, since doping levels on the front surface of the solar cell that are less than about 60 Ω/sq will tend to inhibit light absorption, and thus decrease solar cell efficiency.

At step 406, the substrate is cleaned and etched to remove any glass formed on the surfaces. Phosphorous glass that may have formed during the diffusion process should be removed. For example, a phosphosilicate glass (PSG) may be formed on the top surface of the silicon bulk layer 305 which may then be etched off using an etchant, such as HF acid. The PSG etch may be performed globally. In one example, phosphorous glass is etched from the front surface 305 and the rear surface 306. In one embodiment the etch chemistry used is HF for the front surface and a combination of HNO₃ and HF is used for the rear surface. An inline etch float process may be also used where the substrate floats on the rear surface in the desired etch chemistry to preferentially etch the rear surface of the substrate.

Next, at step 408, as shown in FIG. 3B, a charge compensating region 317 is formed on at least a portion of the rear surface 306 by implanting a dopant on the rear surface 306. The charge compensating region 317 is doped with a third doping element of the same doping type as the first doping element. For example, the dopant may be a p-type dopant such as boron. Other possible p-type dopants include aluminum, indium, and gallium. In another embodiment, such as when the solar cell 310 is an n-type solar cell, the doped region 317 may be implanted with an n-type dopant. Depending on the type of solar cell device, i.e. what type of doped substrate used to manufacture the solar cell device, a small negative or small positive charge may be desired at the interface with a dielectric to reduce recombination loss. In one embodiment of step 408 the whole back surface 306 is doped with a p-type dopant, such as boron. In another embodiment, a selective portion of the back surface 306 is doped with boron.

The charge compensating region 317 is formed by doping a portion of the substrate to a certain level so that it becomes a low dose region that is primarily at the surface to compensate the charge at dielectric layer. Doping may be performed at very low energy implant levels such as 2-50 keV and at dosages from between 1×10¹¹ per centimeters squared to 1×10¹³ per centimeters squared. The depth of the dopant may be 1.5 micron or less, such as 1 micron. In another embodiment the dopant depth is less than 100 nm. For example, a boron implant may be performed at 20 keV to a depth of 64 nm. Generally, the implant should be shallow to not cause too much interference with the channel conductance. In another embodiment, the charge compensating region could include a portion of the dielectric passivation layer, i.e. the charge compensating region may include a portion of the dielectric passivation layer, the interface between the dielectric passivation layer and the substrate, and a portion of the substrate.

It is believed that implantation or other doping means of selected impurities near the interface to form the charge compensation region extrinsically controls the surface potential of dielectrically passivated surfaces. “Intrinsic” means the inherent surface charge due to the chemistry of the dielectric-silicon which may be small and positive for thermal oxides, etc. Thus, the surface potential may be controlled independent of the silicon substrate dopant type and/or amount.

Various doping methods may be used to dope the charge compensating region 317. For example, a plasma ion immersion implantation (PIII) may be used to implant the dopant. Pill may be less expensive and easier to scale in the area compared to traditional implanters using beam lines. In another embodiment, a furnace may be used to form the charge compensating region 317. The entire substrate surface may be doped when using a furnace method. However, the uniformity if likely poor as very high temperatures may be required. Additionally, if a glass is formed, such as a boronsilicate glass (BSG), it is typically difficult to etch and remove to form the charge compensating region 317. The dopant may then optionally be activated in at a temperature from 800° C. to 900° C. for 5 to 60 minutes. However, the charge compensating region 317 may alternatively be activated in a later step, such as in step 416.

Next, at step 410, in one embodiment, a thin passivation and/or antireflection layer, as shown in FIG. 3C, may be formed over the front surface 305 and/or portions back surface 306 including the charge compensating region 317. The thin passivation and/or antireflection (ARC) layer may be a dielectric layer, preferably comprising a nitride (e.g., silicon nitride), that is preferably disposed on front cell surface 305 in order to passivate the surface and provide an anti-reflection coating. In one embodiment, a passivation and ARC layer is formed on the front surface 305 and then a passivation and ARC layer is formed on the rear surface 306. In one embodiment, the thin passivation and/or antireflection layer is formed using a conventional PECVD, thermal CVD or other similar formation process. The passivation layer thickness may be between about 75-85 nm on both front and rear surfaces, although the rear surface may be as thin as 30 nm in some embodiments.

Next, in some embodiments the passivation layer may be patterned using a laser or etch gel to form grid lines for the p-type contacts, though this step is optional. In other embodiments, the later steps of forming the p-type contacts themselves are able to pattern the passivation layer during formation of the p-type contacts.

At box 412, as illustrated in FIG. 3D, a negative conductivity type gridline, of which front side contact 307 may be a part, is deposited over a region of the front surface 305 using a conventional deposition process, such as a screen printing process. In one embodiment, the front side contact 307 is disposed over the n+ region 302 formed on/within a substrate 310 (e.g., p-type silicon substrate), and comprises a silver containing material. Most silver (Ag) pastes deposited by a screen printing process may contain materials, such as an oxide frit, that facilitate alloying through any surface oxides, or through an antireflection coating. However, in some embodiments, the front side contact 307 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr). In some embodiments, the silver pastes may include glass frits to dissolve the passivation layer and allow the silver to make only contact with the silicon.

At box 414, as illustrated in FIG. 3, a positive conductivity type gridline, such as back contact layer 320, is deposited on the rear surface 306 including the rear surface passivation layer 317. A backside contact 321 is formed as part of the back contact layer 320 and traverses the rear surface passivation layer 315 to electrically couple the back contact layer 320 with the substrate 310. The electrical connection may be directly with the substrate 310 or indirectly by contacting the charge compensating region 317, as shown in FIG. 3D. In one embodiment, the back contact layer 320 material comprises an aluminum material that is able to form a p-type contact. However, in some embodiments, the first grid line 522 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr). In other embodiments, if the passivation layer was patterned, the aluminum contact layer is put in the openings. In another embodiment, Ag:Al pads may be optionally printed on the back contact layer to improve solderability and enable interconnection of the solar cells on the rear side if desired.

At box 416, a conventional contact firing process is performed to assure that the front and rear electrical contacts and gridlines 307, 320, 321 make a good electrical contact to the desired regions of the substrate 310. In this step, the substrate is heated to desirable temperature to form a good electrical contact between the front contact 307 and the substrate 302, and the back contact layer 320 and backside contact 321 and the substrate 310. For example, the firing process may be performed in two parts. The first part may be performed as an organic burn off at 500° C. for a few minutes followed by a second part at a temperature between 700° C. and 800° C. for 10-30 seconds.

FIG. 3D thus shows a solar cell device 300, comprising a substrate 310 comprising a semiconductor material doped with a first doping element, the substrate 310 comprising a front surface 305 and a rear surface 306 opposite the front surface. The solar cell device 300 has a doped region 302 formed on the front surface 305 and in the substrate 310, wherein the doped region 302 is doped with a second doping element that is of an opposite doping type to the first doping element. A charge compensating region 317 is formed on the rear surface 306, wherein the charge compensating region 317 is doped with a third doping element of the same doping type as the first doping element. The solar cell device 300 also includes a rear surface passivation layer 315 formed on the charge compensating region 317. The solar cell device also includes a back contact layer 320 comprising a conductive material that is formed on the rear surface passivation layer 317. A backside contact 321 traverses the rear surface passivation layer 315 to electrically couple the back contact layer 320 with the semiconductor material.

In another embodiment of the invention, a voltage-threshold implant may be preferably used to modify the region between the negative- and positive-polarity contacts in a back-contact cell as described below. The implant is preferably shallow and provides for independent control of the surface potential of the passivation layer

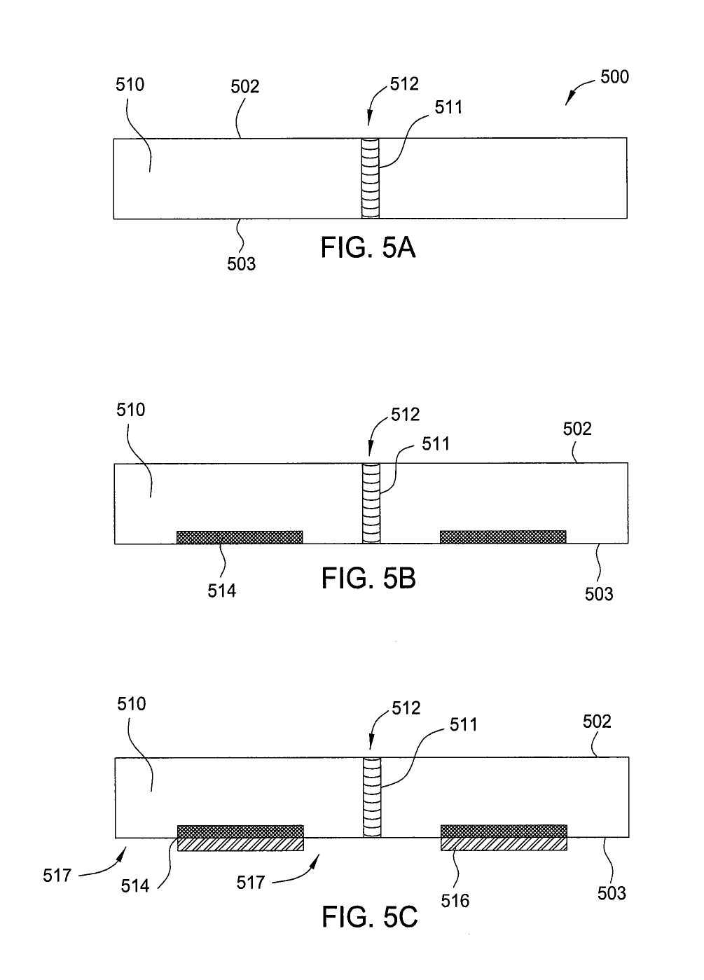

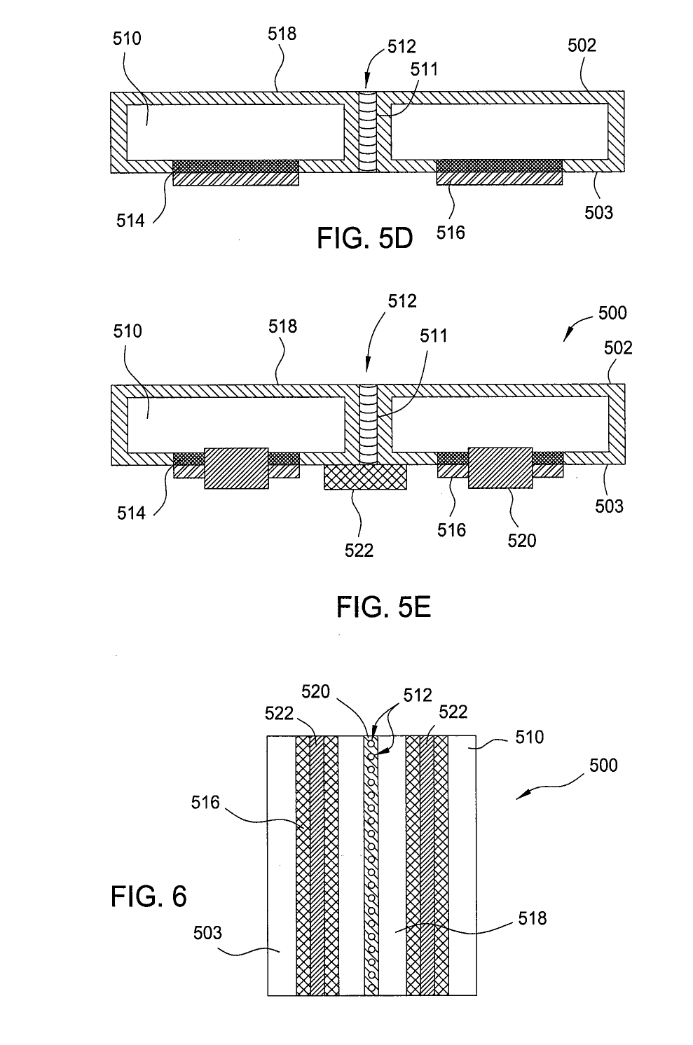

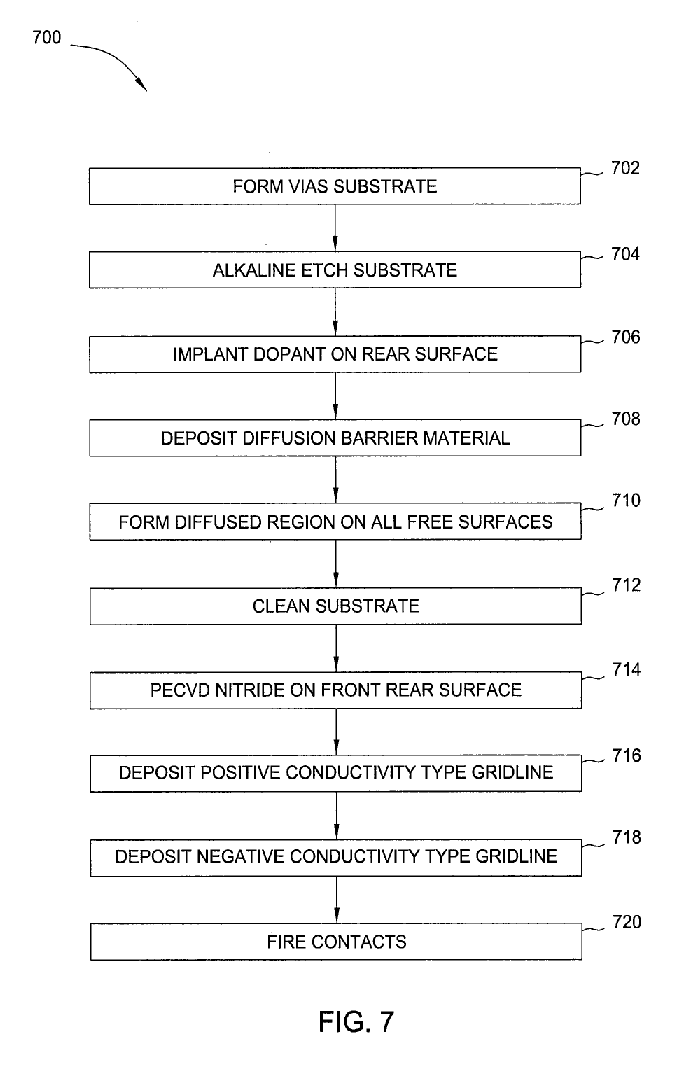

A back-contact cell device, such as a EWT solar cell device 500, may be formed using embodiments of the invention. FIGS. 5A-5E depict cross-sectional views of a portion of a of EWT c-Si solar cell substrate corresponding to various stages of the process 700 illustrated in FIG. 7. FIG. 6 depicts a rear surface of an EWT solar cell comprising a gridline disposed over vias architecture.

In one embodiment the method of forming a EWT solar cell device 500 includes forming an array of vias 512 in a substrate 510 that is doped with a first doping element, such as a p-type dopant. The array of vias 512 is formed between a front surface 502 and a rear surface 503 of the substrate 510. At step 702, and as shown in FIG. 7, a plurality of vias 512, or holes, are formed through the solar cell substrate 510 as shown in FIGS. 5A and 6. The vias 512 formed through the substrate 510 connect the front surface 502 to the rear surface 503 through a via surface 511, and are preferably formed by a laser drilling process. The vias 512 may also be formed by other processes, such as dry etching, wet etching, mechanical drilling, or water jet machining. Laser drilling preferably uses a laser that is able to deliver sufficient power and/or electromagnetic radiation intensity at the operating wavelength to form the vias 512 in the shortest time, such as between about 1,000 and 20,000 holes per second. Shortening the via formation time will generally increase the substrate processing throughput and reduce the amount of heat and stress induced in the substrate during the via formation process. One laser that may be employed is a Q-switched Nd:YAG laser. The time required to form vias 512 in progressively thinner substrates will generally be proportionally reduced. The diameter of the formed via 512 may be from about 25 to 125 μm, preferably from about 30 to 80 μm.

In one embodiment, when employing thin solar cell substrates, such as substrates with a thickness of 100 μm or less, the via diameter is approximately greater than or equal to the substrate thickness. The via 512 density per unit surface area of the front surface 502, or rear surface 503, is dependent on the acceptable total series resistance loss due to current transport in the emitter region formed on the front surface 502 through the vias 512 to the rear surface 203 and second gridline 520. In general, the density of vias 512 can be decreased as the sheet resistance of the emitter region is reduced, such as determined by Ohms per square (Ω/sq). One skilled in the art will appreciate that as the diameter of the vias 512 increases the cross-sectional area through which the generated current can pass, and thereby reduce the resistance. However, increasing the size and/or density of vias 512 will affect the amount of energy required to form each of the vias, the throughput of the via formation process, and the usable surface area of the front side of the solar cell device.

Next, at step 704, the surfaces of the substrate 510, such as the front surface 502, rear surface 503, and via surface 511 are etched to remove any undesirable material or crystallographic defects from the wafer production process and the laser machining process. In one embodiment, the etch process may be performed using a batch etch process in which the substrates are exposed to an alkaline etching solution. The substrates can be etched using a wet cleaning process in which they are sprayed, flooded, or immersed in an etchant solution. The etchant solution may be a conventional alkaline cleaning chemistry, such as a potassium hydroxide, or other suitable and cost effective etching solution. This step might additionally texture the surface for improved light collection.

Next, at step 706, as shown in FIG. 5B, a charge compensating region 514 is formed on a portion of the rear surface 503 by implanting a dopant on the rear surface 503. The charge compensating region 514 is doped with a third doping element of the same doping type as the first doping element. For example, the dopant may be a p-type dopant such as boron. Other possible p-type dopants include aluminum, indium, and gallium. In another embodiment, such as when the solar cell 510 is an n-type solar cell, the doped region 514 may be implanted with an n-type dopant. Depending on the type of solar cell device, i.e. what type of doped substrate used to manufacture the solar cell device, a small negative or small positive charge may be desired at the interface with a dielectric to reduce recombination loss.

In one embodiment the whole back surface 503 is doped with a p-type dopant, such as boron. In another embodiment, a selective portion of the back surface 503 is doped with a p-type dopant, such as boron. Doping may be performed at very low energy implant levels such as 2-50 keV and at dosages from between 1×10¹¹ per centimeters squared to 1×10¹³ per centimeters squared. The depth of the dopant may be 1.5 micron or less, such as 1 micron. In another embodiment the dopant depth is less than 100 nm. For example, a boron implant may be performed at 20 keV to a depth of 64 nm. Generally, the implant should be shallow to not cause too much interference with the channel conductance. Various doping methods may be used to dope the charge compensating region 514. For example, a plasma ion immersion implantation (PIII) may be used to implant the dopant. Pill may be less expensive and easier to scale in the area compared to traditional implanters using beam lines. In another embodiment, a furnace may be used to form the charge compensating region 514. The entire substrate surface may be doped when using a furnace method. However, the uniformity if likely poor as very high temperatures may be required. Additionally, if a glass is formed, such as a boronsilicate glass (BSG), it is typically difficult to etch and remove to form the charge compensating region 514.

Next, at step 708, as shown in FIG. 5C, a dielectric passivation layer 516 is formed on the charge compensating region 514. The dielectric passivation layer 516 is disposed over the rear surface 503 of the substrate 510. In one embodiment, the dielectric passivation layer 516 comprises an oxide and/or nitride material. In one example, the dielectric passivation layer 516 comprises a silicon oxide, a silicon nitride or a metal oxide material that is disposed over a p-type silicon substrate 510 and the charge compensating region 514. In one embodiment, the dielectric passivation layer 516 may be formed on the rear surface 503 so that isolated regions 517 of the substrate 510 are left exposed. In one configuration, the deposited dielectric passivation layer 516 is deposited in a pattern to form isolated regions 517 that comprise a series of holes or long channel like regions of exposed substrate surface, which are surrounded, and thus are isolated from other regions of the rear surface 503. A patterned dielectric passivation layer 516 may be formed by use of a screen printing, stenciling, ink jet printing, rubber stamping or other useful application method that provides for accurate placement of the dielectric passivation layer 516 on these desired locations of the substrate. In some embodiments, the dielectric passivation layer 516 is formed over the rear surface 503 and/or charge compensating region 214 by a CVD deposition and then patterned with a patterning process, such as screen-printed resist followed by chemical etch. The dielectric barrier layer 516 may then be subject to a firing process at around 500° C. for 103 minutes to burn of organics.

Next, the substrate 201 may be cleaned to remove any undesirable formed oxide materials and/or surface contamination found on the surface of the substrate after step 308 has been performed. In one embodiment, the clean process may be performed using a batch cleaning process in which the substrates are exposed to a hydrofluoric acid (HF) containing cleaning solution. The substrates can be cleaned using a wet cleaning process in which they are sprayed, flooded, or immersed in a cleaning solution. For example, the etch/clean chemistry may be a HF solution with a small amount of oxidizing agent added. In another embodiment, step 310 may include an HCl clean with an oxidizing agent such as peroxides, followed by an HF dip.

Next, at step 710, as shown in FIG. 5D, a diffused or doped region 518 is formed on at least a portion of the front surface 502, on a surface of the vias 511 in the array of vias 512, and at least a portion of the rear surface 503. The doped region 518 is doped with a second doping element that is of an opposite doping type to the first doping element. In one embodiment, the doped region 518 comprises an n⁺ diffusion region (e.g., phosphorous doped) formed in a p-type solar substrate (e.g., boron doped silicon substrate). The diffused region 518 formation process may be performed by use of a conventional furnace doping process that can drive-in one or more dopant atoms. In one example, a POCl₃ diffusion step is performed to produce a diffused region 518 that is an n⁺ doped region. The diffusion process may be done at 850° C. for 20-30 minutes. Alternatively, an inline diffusion process could also be performed, where a dopant source, such as phosphorous source, is applied on both surfaces of the substrate. The substrate may then pass through a belt furnace to diffuse the phosphorous. Additionally, step 710 may activate the dopant in the charge compensating region 514. Some phosphorous glass that may have formed during the firing process may then need to be removed.

In general, it is desirable to create a doping profile in the front surface 502 that is different than the doping profile in the via surface 511 and back surface 503, so that the amount of light collected at the front surface 502 is maximized and the series resistance formed between the front surface 502 and the gridline 520 formed on the rear surface 503 is reduced. In one embodiment, it is desirable to create a doping profile in the portion of the diffused region 518 formed on the front surface 502 that has a sheet resistance of between about 60 Ω/sq and about 200 Ω/sq, and a doping profile in the portion of the diffused region 225 formed on the via surface 511 and the rear surface 503 that has a sheet resistance of between about 20 Ω/sq and about 80 Ω/sq, such as about 40 Ω/sq. In another embodiment, to simplify the solar cell device formation process a single dopant concentration profile is created in the diffused region 518, which is formed across the front surface 502, via surface 511 and portions of the back surface 503. In this configuration, for example, the dopant concentration in the diffused region 518 is doped to achieve a sheet resistance between about 60 Ω/sq and about 80 Ω/sq. In one embodiment, the dopant concentration in the diffused region 518 is doped to achieve a sheet resistance of greater than about 60 Ω/sq, since doping levels on the front surface of the solar cell that are less than about 60 Ω/sq will tend to inhibit light absorption, and thus decrease solar cell efficiency.

Next, at step 712, the substrate 510 may be cleaned to remove any undesirable formed oxide materials and/or surface contamination found on the surface of the substrate after step 710 has been performed. In one embodiment, the clean process may be performed using a batch cleaning process in which the substrates are exposed to a hydrofluoric acid (HF) containing cleaning solution. The substrates can be cleaned using a wet cleaning process in which they are sprayed, flooded, or immersed in a cleaning solution. For example, the etch/clean chemistry may be a HF solution with a small amount of oxidizing agent added. In another embodiment, step 310 may include an HCl clean with an oxidizing agent such as peroxides, followed by an HF dip. Optionally, the dielectric passivation layer 516 may be etched using an HF solution of 10-20 parts water to 1 part HF, where the HF is a 49% HF/water solution.

Next, at step 714, in one embodiment, a thin passivation and/or antireflection layer (not shown) may be formed over the front surface 502, via surface 511 and/or portions back surface 503. The thin passivation and/or antireflection (ARC) layer may be a dielectric layer, preferably comprising a nitride (e.g., silicon nitride), that is preferably disposed on front cell surface 502 in order to passivate the surface and provide an anti-reflection coating. In one embodiment, a passivation and ARC layer is formed on the front surface 502 and portions of the vias 512 in step 714, and then a passivation and ARC layer is formed on the rear surface 503 and portions of the vias 512. In one embodiment, the thin passivation and/or antireflection layer is formed using a conventional PECVD, thermal CVD or other similar formation process. The passivation layer thickness may be between about 75-85 nm on both front and rear surfaces, although the rear surface may be as thin as 30 nm in some embodiments.

Next, in some embodiments the passivation layer may be patterned using a laser or etch gel to form grid lines for the p-type contacts, though this step is optional. In other embodiments, the later steps of forming the p-type contacts themselves are able to pattern the passivation layer during formation of the p-type contacts.

At box 716, as illustrated in FIG. 5E, a first gridline 522 is deposited on the rear surface 503 and a distance along the rear surface 503 from the array of vias 512. The first gridline 522 traverses the dielectric passivation layer 516 and is electrically connected to the substrate 510 doped with the first doping element. The electrical connection may be directly with the substrate 510 or indirectly by contacting the charge compensating region 514, as shown in FIG. 5E. The first gridline 522 is deposited over the isolated regions formed between portions of the diffusion barrier material 516 using a conventional deposition process, such as a screen printing process. In one embodiment, the first grid line 522 material comprises an aluminum material that is able to form a p-type contact. However, in some embodiments, the first grid line 522 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr). In other embodiments, if the passivation layer was patterned, the aluminum contact layer is put in the openings.

At box 718, as illustrated in FIG. 5E, a second gridline 520 is deposited over a region of the rear surface 503 using a conventional deposition process, such as a screen printing process. In one embodiment, the second grid line 520 is disposed over the n+ region formed on a substrate 510 (e.g., p-type silicon substrate), and comprises a silver containing material. Most silver (Ag) pastes deposited by a screen printing process may contain materials, such as an oxide frit, that facilitate alloying through any surface oxides, or through an antireflection coating. However, in some embodiments, the second grid line 250 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr). In some embodiments, the silver pastes may include glass frits to dissolve the passivation layer and allow the silver to make only contact with the silicon.

In some embodiments, the aluminum paste and rear PECVD SiNₓ are typically selected so that the aluminum does not fire through the SiNₓ film. The boron implant could alternatively be performed after, the deposition of the dielectric on the rear surface. It may be advantageous to implant through the dielectric in order to get a shallow implant in some embodiments. Other p-type dopants (e.g., In, Al) may alternatively be used instead of boron, and other dielectric coatings may alternatively be used instead of SiNₓ.

At box 720, a conventional contact firing process is performed to assure that the first and second gridlines 520, 522 make a good electrical contact to the desired regions of the substrate 510. In this step, the substrate is heated to desirable temperature to form a good electrical contact between the first gridline 520 and the substrate 510, and the second gridline 522 and the substrate 510. For example, the firing process may be performed in two parts. The first part may be performed as an organic burn off at 500° C. for a few minutes followed by a second part at a temperature between 700° C. and 800° C. for 10-30 seconds.

FIG. 5E thus shows a solar cell device including a substrate 510 having an array of vias 512 formed between a front surface 502 and a rear surface 503 of the substrate 512, wherein the substrate is doped with a first doping element. A charge compensating region 514 is formed on a portion of the rear surface 503, wherein the charge compensating region 514 is doped with a third doping element of the same doping type as the first doping element. The solar cell device 500 also includes a dielectric passivation layer 516 formed on at least a portion of the charge compensating region 514, and a doped region 518 formed on at least a portion of the front surface 502, a surface of the vias 511 in the array of vias 503, and at least a portion of the rear surface 503 adjacent the charge compensating region 514. The doped region is doped with a second doping element that is of an opposite doping type to the first doping element as described above.

While the foregoing is directed to embodiments of the invention, other and further embodiments of the invention may be devised without departing from the basic scope thereof. Variations and modifications of the present invention will be obvious to those skilled in the art and it is intended to cover all such modifications and equivalents.

What is claimed is:

1. A method of forming a solar cell, comprising:
disposing an amount of impurities into a charge compensating region formed on a rear surface of a substrate; and
forming a rear surface passivation layer over at least a portion of the charge compensating region, wherein the amount of the impurities disposed in the charge compensating region is selected to compensate for an amount of charge formed in the rear surface passivation layer.

2. The method of claim 1, wherein the impurities comprise charge centers in the dielectric.

3. The method of claim 1, further comprising:
using ion implantation to incorporate the impurities into the charge compensating region.

4. The method of claim 1, wherein the impurities comprise dopants in the silicon.

5. The method of claim 3, wherein the ion implantation parameters for dopant implant include at least one of implanting the impurities at a dosage from between 1×10¹¹ to 1×10¹³ per centimeters squared and at an implant energy from between 2 to 50 keV.

6. The method of claim 1, wherein the first and third doping elements are a p-type dopant and the second doping element is an n-type dopant.

7. The method of claim 1, wherein the charge compensating region has a depth of 1.5 microns or less.

8. A method of forming a solar cell device, comprising:
forming an array of vias in a substrate that is doped with a first doping element, wherein the array of vias is formed between a front surface and a rear surface of the substrate;
forming a charge compensating region on a portion of the rear surface, wherein the charge compensating region is doped with a third doping element of the same doping type as the first doping element;
forming a dielectric passivation layer on the charge compensating region;
forming a doped region on at least a portion of the front surface, on a surface of the vias in the array of vias, and at least a portion of the rear surface, wherein the doped region is doped with a second doping element that is of an opposite doping type to the first doping element; and
depositing a first gridline on the rear surface and a distance along the rear surface from the array of vias, wherein the first gridline traverses the dielectric passivation layer and is electrically connected to the substrate doped with the first doping element.

9. The method of claim 8 further comprising:
depositing a second gridline on the rear surface on the doped region formed on the rear surface.

10. The method of claim 8, wherein the first and third doping elements are a p-type dopant and the second doping element is an n-type dopant.

11. The method of claim 8, wherein forming the charge compensating region comprises implanting the third doping element at a dosage from between 1×10¹¹ to 1×10¹³ per centimeters squared.

12. A solar cell device, comprising:
a substrate comprising a semiconductor material doped with a first doping element, the substrate comprising a front surface and a rear surface opposite the front surface;
a doped region formed on the front surface and in the substrate, wherein the doped region is doped with a second doping element that is of an opposite doping type to the first doping element;
a charge compensating region formed on the rear surface, wherein the charge compensating region is doped with a third doping element of the same doping type as the first doping element;
a rear surface passivation layer formed on the charge compensating region;
a back contact layer comprising a conductive material formed on the rear surface passivation layer; and
a backside contact that traverses the rear surface passivation layer to electrically couple the back contact layer with the semiconductor material.

13. The solar cell device of claim 12, wherein the first and third doping elements are a p-type dopant and the second doping element is an n-type dopant.

14. The solar cell device of claim 12, wherein the charge compensating region has a depth of 1 micron or less.

15. A solar cell device, comprising:
a substrate having an array of vias formed between a front surface and a rear surface of the substrate, wherein the substrate is doped with a first doping element;
a charge compensating region formed on a portion of the rear surface, wherein the charge compensating region is doped with a third doping element of the same doping type as the first doping element;
a dielectric passivation layer formed on at least a portion of the charge compensating region; and
a doped region formed on at least a portion of the front surface, a surface of the vias in the array of vias, and at least a portion of the rear surface adjacent the charge compensating region, wherein the doped region is doped with a second doping element that is of an opposite doping type to the first doping element.

16. The solar cell device of claim 15, further comprising:
a first gridline disposed on the rear surface and a distance along the rear surface from the array of vias and traverses the dielectric passivation layer to electrically connect with the substrate doped with the first doping element; and
a second gridline disposed on the doped region formed on the rear surface and adjacent the array of vias.

17. The solar cell device of claim 15, wherein the charge compensating region has a depth of 1 micron or less.
